(19) United States
(12) Patent Application Publication
(10) Pub. No.: US 2011/0164374 A1
(43) Pub. Date: Jul. 7, 2011

(54) PORTABLE STORAGE DEVICE

(76) Inventors: Tzu-Wei TAI, Taipei (TW); Chao-Ming Chu, Taipei (TW)

(21) Appl. No.: 12/841,396

(22) Filed: Jul. 22, 2010

(30) Foreign Application Priority Data
Jan. 6, 2010 (TW) 099100175

(51) Int. Cl. H05K 7/00

(52) U.S. Cl. 361/679.33

(57) ABSTRACT

A portable storage device includes a body and a cable. The body has a receiving slot with an opening. The cable is received in the receiving slot and is electrically connected with the body. The cable has at least one bending portion with an included angle less than 90 degree, thereby flexibly extends the cable along a longitudinal extension axis and avoids non-linear twist or curl occurring on the cable, so as to allow a convenient folding and storing of the connecting cable.

### CROSS REFERENCE TO RELATED APPLICATIONS

This Non-provisional application claims priority under 35 U.S.C. §119(a) on Patent Application No(s). 099100175 filed in Taiwan, Republic of China on Jan. 6, 2010, the entire contents of which are hereby incorporated by reference.

### BACKGROUND OF THE INVENTION

1. Field of Invention

The invention is relative to a portable electronic device, and more particularly, to a portable storage device.

2. Related Art

With highly development of technology, all kinds of electronic products are utilized in people's daily life. Particularly, with demand of light-weight, mini-size and portability, some electronic products, such as digital storage device, are modified to be in a compact structure.

As shown in FIG. 1, a conventional storage device 1 comprises a hard disk 11 and a body 12. The hard disk 11 is disposed in the body 12. Except that, the storage device 1 has a cable 13 with a connector 131 (may be a universal serial bus, USB) to connect with an external electronic device (such as a computer, not shown) for digital data transmission.

However, as well known, the cable 13 is linear and extends from the conventional storage device 1, thus, the cable 13 is bound to be detached therefrom or wound on the body 12 while the storage device 1 is not used. However, deal with the cable matter can be tedious and inconvenient, and the cable may occupy too much space.

What's more, during drawing and dragging the cable 13 for connection, a non-linear twist (for example, bent in a circular manner, a waved manner or an indirectional manner) is inevitably occurring on the cable 13. With such, a neatening of the cable 13 is necessary, and damage may be easily caused to the cable 13.

### SUMMARY OF THE INVENTION

Present invention provides a portable storage device, which may store a cable in a body, thereby avoids space occupation or damage to the cable, furthermore, presents a neat appearance of the portable storage device.

The portable storage device in accordance with present invention comprises a body and a cable. The body has a storing unit and a receiving slot with an opening formed thereon. The cable is connected with the body and extendable from the opening of the receiving slot, which is non-circular in cross section and has at least one bending portion. The bending portion of the cable is bent with an included angle less than 90 degree.

For further illustration, it is provided that the cable has one bending portion in a “U” shape or a “V” shape when extended. On the other hand, provided that the cable has multiple bending portions, the cable is in a waved shape, a zigzag shape or the like. Anyway, it is noted that the bending portion is flexible/resilient and provides a flexibility to extend the cable from the receiving slot of the body when free from latching.

While storing the cable, a user may fold and retract the cable along a longitudinal extension axis, and eventually stored in the receiving slot completely.

In detail, multiple sections of the cable are arranged and may be stacked in a plane along the longitudinal extension axis, thereby the sections may be received completely in the receiving slot of the body. Furthermore, a latch of the cable may engage a detent formed on the body to retain the cable in the receiving slot. When the cable is used, the user may detach the cable, then, extends the cable by flexibility of itself and then drawing and dragging the cable. Preferably, a cap is provided to cover the opening to position the cable and avoid infringement of external object.

It is noted, the receiving slot is accommodated to the folded cable and thus allows the cable be completely stored in the receiving slot to ensure a neat appearance of the portable storage device.

To sum up, since the cable is completely stored in the receiving slot of the body, the portable storage device in accordance with present invention is effectively avoid extra space occupation. Moreover, with implement of the bending portion, the cable is extending along a longitudinal extension axis and the sections thereof are expanding in a plane. With such, during drawing and dragging the cable for connection, non-linear twist is not occur on the cable, therefore, the user don't have to neaten the cable at first, and a convenience is then provided.

These and other features, aspects and advantages of the present invention will become better understood with regard to the following description, appended claims, and accompanying drawings.

### BRIEF DESCRIPTION OF THE DRAWINGS

FIG. 1 is a sketch diagram showing a conventional portable storage device;

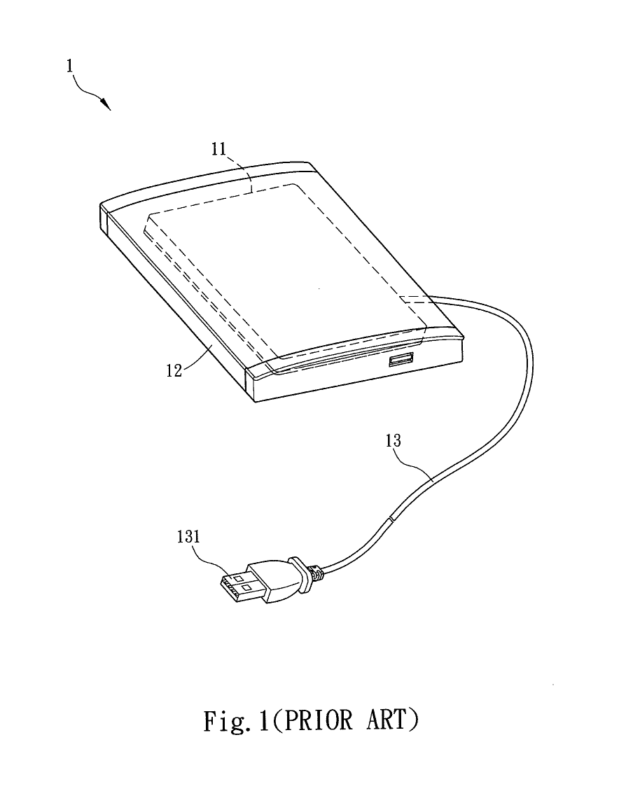

FIG. 2A is a perspective view showing the portable storage device is used;

FIG. 2B is a perspective view of the portable storage device in 2A illustrating a folded cable;

FIG. 3A is a perspective view of the portable storage device in 2A showing a protruding portion;

FIG. 3B is a perspective view of the portable storage device in 2A showing a cap; and

FIG. 4 is a sketch diagram showing a further embodiment of the portable storage device in accordance with present invention.

### DETAILED DESCRIPTION OF THE INVENTION

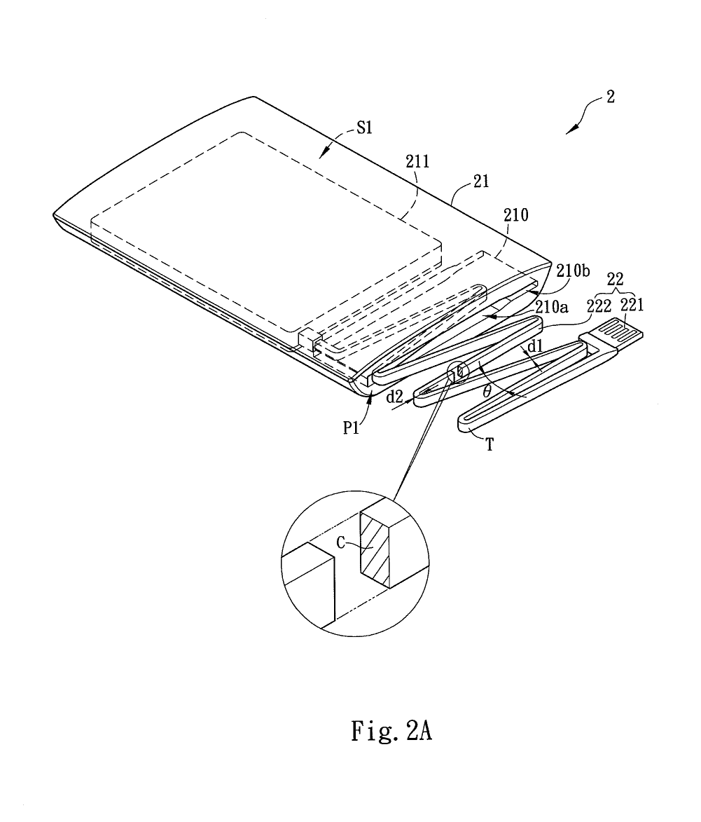

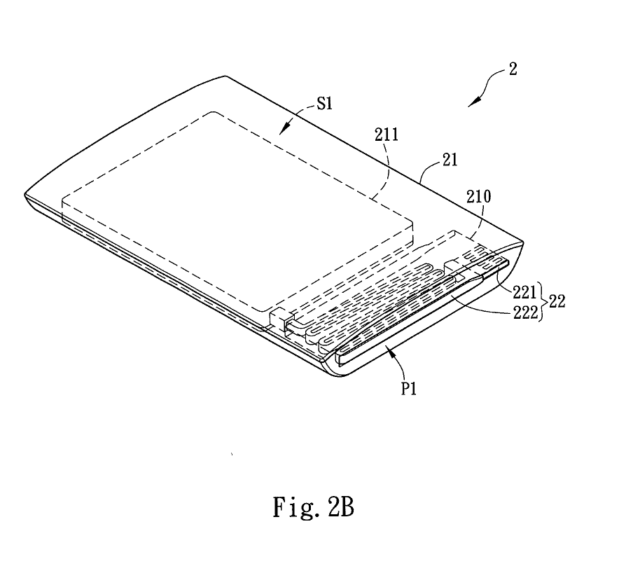

With reference to FIGS. 2A and 2B that are sketch diagrams of the portable storage device in accordance with a preferred embodiment of present invention. FIG. 2A illustrates an unfolded status, and FIG. 2B illustrates a folded status.

The portable storage device 2 in accordance with present invention comprises a body 21 and at least one cable 22. Note that the portable storage device 2 mentioned in present invention may be any kind of electronic devices that complete an electrical connection via a cable, such as portable hard drives, portable Optical Disc Drives, electronic dictionaries, e-Books, hand-held PCs, Ultra Mobile PC (UMPC), Tablet Personal Computers, Differential scanning calorimetrys (DSC), Digital Videos (DV), Game devices, GPS devices or mobile phones.

The body 21 has a storing unit 211 that may be Hard Disk Drive (HDD) or Solid State Drive (SSD) built therein. Preferably, the body 21 has a space S1 formed therein to receive the storing unit 211.

The body 21 has at least one receiving slot 210. The receiving slot 210 is formed in at least one side P1 of the body 21 and is communicated with the space S1. In present embodiment, one receiving slot 210 is formed in the body 21. The receiving slot 210 is formed in a right side of the body 21 and has an opening 210a and a detent 210b formed adjacent to the opening 210a.

An end of the cable 22 is connected with the storing unit 211, and the other end of the cable 22 is adapted to connect external electronic devices. The cable 22 is stored in the receiving slot 210 after folded, and the receiving slot 210 is accommodated to the folded cable 22 and thus allows the cable 22 be completely stored in the receiving slot 210 to present a neat appearance. Thereby the cable 22 is completely stored in the receiving slot 210 of the body 21 and extra space occupation is effectively avoided.

The cable 22 has multiple sections that are arranged and may be stacked in a plane along a longitudinal extension axis (not shown), thereby the cable 22 is extended along the longitudinal extension axis and the sections thereof are expanded in a plane. With such, during drawing and dragging the cable 22 for connection, non-linear twist would not occur on the cable 22, therefore, the user don't have to neaten the cable 22 at first, and a convenience is then provided.

The cable 22 is non-circular in cross section, and may be such as rectangular, elliptic, triangular and the like. As shown in FIG. 2A, the cable 22 is mounted in the receiving slot 210 and may be formed via injection molding means or die casting means, wherein said means are included but not limited thereto.

The cable 22 has at least one bending portion T. For further illustration, provided that the cable 22 has one bending portion T, the cable 22 is in a “U” shape or a “V” shape when extending. On the other hand, provided that the cable 22 has multiple bending portions T, the cable 22 is in a waved shape, a zigzag shape or the like.

The bending portion T is flexible/resilient and provides a flexibility to extend the cable 22 from the opening 210a of the receiving slot 210 of the body 21 when free from latching. In present embodiment, the cable 22 has multiple bending portions T, each of the bending portions T is bent in an included angle θ less than 90 degree.

In present embodiment, a cross section C of the cable 22 is rectangular, and the cable 22 includes a connector 221 and a wire 222. The connector 221 is adapted to connect an external electronic device (not shown) and may be USB, RS-232, IEEE-1394 or SATA connectors.

In present embodiment, the connector 221 is selectively a USB connector with shell removed. Aforementioned detent 210b of the receiving slot 210 corresponds to and engages the connector 221 of the cable 22. The wire 222 has two ends connect respectively to the connector 221 and the storing unit 211.

As shown in FIG. 2A, with the included angle θ of the bending portion T being less than 90 degree, the cable 22 is in a zigzag shape when extending. Moreover, in present embodiment, a width d2 in the bending portion T of the cable 22 is larger than a width d1 in a linear portion of the wire 222, but practical embodiment is not limited thereto. With the width d2 being larger than a width d1, the flexibility of the cable 22 is then increased.

As shown in 2B, when the cable 22 is received in the receiving slot 210, the wire 222 is adjacent to the opening 210a, and the connector 221 is mounted in the detent 210b of the opening 210a of the receiving slot 210 to secure the wire 222 and ensures a complete storing of the cable 22 that keeps in a neat appearance.

The receiving slot 210 may further have a securing portion. The securing portion may be formed in the opening 210a and/or the detent 210b, which engages and secures the connector 221 of the cable 22 folded. Structurally, the securing portion may have a convex or rough surface to provide a friction or positioning.

For further illustration, the securing portion may also be formed in the receiving slot 210, corresponds to and secures with a latch of the cable 22. In practice, the securing portion and the latch may have corresponding convex surface/concave surface, or rough surfaces to achieve the object of positioning.

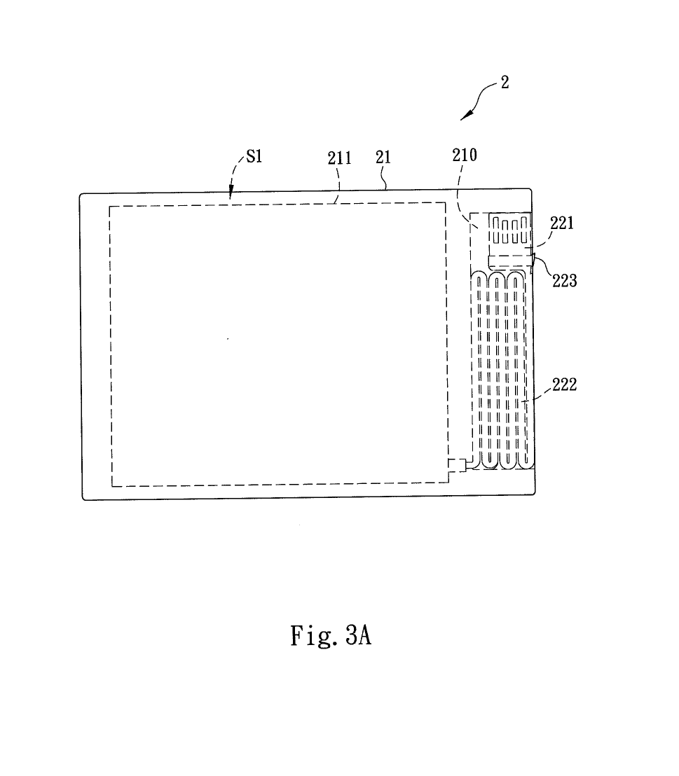

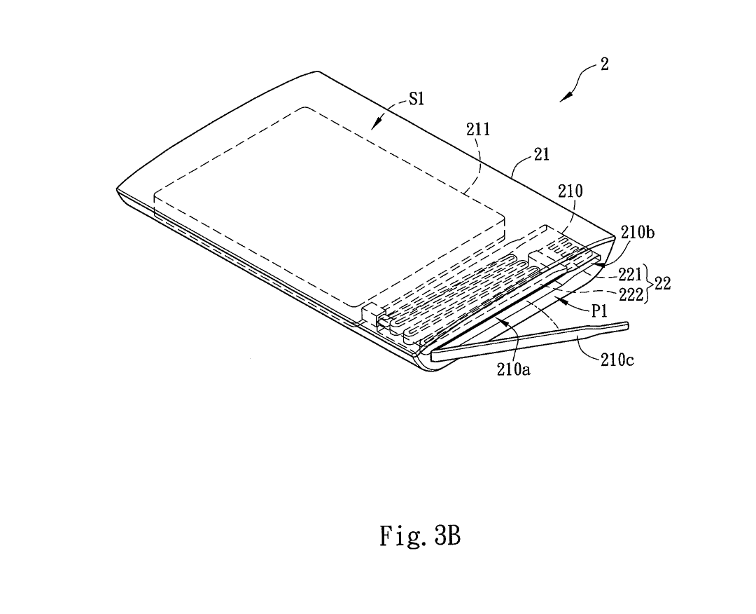

Additionally, as shown in FIG. 3A, the cable 22 has at least one protruding portion 223. The protruding portion 223 protrudes from the opening 210a of the receiving slot 210 while the cable 22 is folded and received in the receiving slot 210, such that a user may detach the connector 221 from the securing portion by pushing the protruding portion 223. Then the cable 22 ejects and extends via flexibility of itself for usual usage. Note that although, in present embodiment, the protruding portion 223 is disposed adjacent to the connector 221, practical implement is not limit thereto.

Furthermore, as shown in FIG. 3B, a cap 210c is mounted in the opening 210a of the receiving slot 210, thereby to position the cable 22 and avoid infringement of external object.

It is known that an electronic device may transmit digital data with the storing unit 211 of the portable storage device 2 via the cable 22. When the portable storage device 2 is not used, the cable 22 is received and secured in the receiving slot 210. With features of the bending portions T that with included angles θ less than 90 degree and rectangular cross section of the cable 22, the cable 22 is extending along the longitudinal extension axis and the sections thereof are expanding in a plane. Therefore, non-linear twist or curl will not occur on the cable 22.

In further practice, the portable storage device may also have two cables disposed in opposite sides of the body. With such dual cable design, power supplying and data transmission speed is improved.

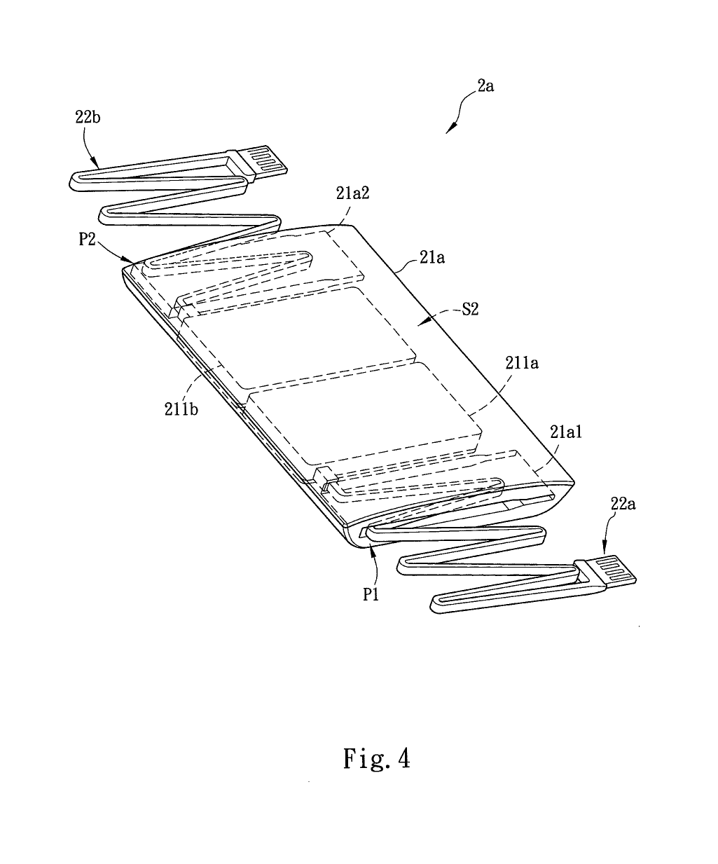

With reference to FIG. 4, in a further embodiment of present invention, the portable storage device 2a is provided. Features of the portable storage device 2a that different from above described portable storage device 2 includes: the portable storage device 2a has two storing unit 211a disposed in a space S2 of the body 21a; and the body has two receiving slots 21a1 and 21a2 to receive two cables 22a and 22b, respectively. The receiving slots 21a1 and 21a2 are formed in two sides P1 and P2 of the body. The cables 22a and 22b are connected in the receiving slots 21a1 and 21a2 for digital data transmission.

The storing unit 211a, 211b, body 21a, receiving slot 21a1, 21a2 and cable 22a, 22b are functionally and structurally similar to the same components of above described embodiment, thus any further illustration thereabout shall not need to be made.

Generally, the portable storage device in accordance with the present invention, with multiple bending portions that is bent and defines included angles less than 90 degree, subdues the cable to extend along a longitudinal axis in a plane. Therefore, the cable is easily retracted and stored in the receiving slot, without non-linear twist occurring on the cable. Since the cable is completely stored in the receiving slot, a neat appearance of the portable storage device is thus guaranteed.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A portable storage device comprising:
a body having a receiving slot with an opening; and
a cable disposing in the receiving slot and electrically connecting to the body and selectively extending from the opening of the receiving slot;
wherein the cable is non-circular in cross section and has at least one bending portion with an included angle less than 90 degree therein.

2. The portable storage device as claimed in claim 1, wherein the bending portion is flexible and provides a flexibility to extend the cable from the opening of the receiving slot.

3. The portable storage device as claimed in claim 1, wherein the receiving slot is accommodated with the cable being folded.

4. The portable storage device as claimed in claim 1, wherein the body further has a detent formed on the body to retain the cable in the receiving slot.

5. The portable storage device as claimed in claim 4, wherein the cable further has a latch; and the receiving slot further has a securing portion corresponding to and securing with the latch.

6. The portable storage device as claimed in claim 1, wherein the cable further has at least one protruding portion protruded from the opening of the receiving slot while the cable is folded and received in the receiving slot.

7. The portable storage device as claimed in claim 1, further has a cap mounted in the opening of the receiving slot.
